(19) United States
(12) Patent Application Publication
(10) Pub. No.: US 2009/0009960 A1
(43) Pub. Date: Jan. 8, 2009

(54) METHOD AND APPARATUS FOR MITIGATING DUST-FOULING PROBLEMS

(76) Inventors: Ronald J. Melanson, Woodside, CA (US); Kenny C. Gross, San Diego, CA (US); Aleksey M. Urmanov, San Diego, CA (US)

Correspondence Address: PVF -- SUN MICROSYSTEMS INC.;C/O PARK, VAUGHAN & FLEMING LLP, 2820 FIFTH STREET, DAVIS, CA, 95618-7759, US

(21) Appl. No.: 11/773,518

(22) Filed: Jul. 5, 2007

(51) Int. Cl. H05K 7/20; G06F 17/50

(52) U.S. Cl. 361/687; 361/695; 703/2

(57) ABSTRACT

Embodiments of the present invention provide a system for preventing dust-fouling in a computer system. During operation of the computer system, the system monitors the computer system and determines if the computer system is becoming dust-fouled. If so, the system reverses fans in the computer system to circulate air through the computer system in the opposite direction to dislodge and disperse dust from the computer system.

### BACKGROUND

1. Field of the Invention

Embodiments of the present invention relate to techniques for enhancing the availability and reliability of computer systems. More specifically, embodiments of the present invention relate to a technique for reducing dust-fouling in a computer system.

2. Related Art

In an effort to conserve space in datacenters, computer server internals are becoming increasingly dense. Hence, components within the servers are becoming more crowded. At the same time, to assure adequate heat removal, airflow rates within servers are increasing. As a result, there is an increased likelihood of “dust-fouling” for components such as power supplies and heat sinks. (A component is dust-fouled when the buildup of dust on the component interferes with the normal operation of the component.)

As components become dust-fouled, the components are unable to shed heat and the temperature of the components can increase. Components can therefore experience over-temperature events which can lead to unexpected server shut-downs or shortened component life-spans.

Some servers lack dust filters on the air intake ducts. Unlike servers that include air filters (which can be changed by users to avoid excessive dust buildup), servers with no air filters are generally not serviceable by the user if the dust-fouling causes an over-temperature shutdown. Moreover, even servers that provide air filters can experience dust-fouling if a user neglects to change the filter at the recommended service intervals.

Hence, what is needed is a method and apparatus for mitigating the effects of dust-fouling in servers.

### SUMMARY

Embodiments of the present invention provide a system for preventing dust-fouling in a computer system. During operation of the computer system, the system monitors the computer system and determines if the computer system is becoming dust-fouled. If so, the system reverses fans in the computer system to circulate air through the computer system in the opposite direction to dislodge and disperse dust from the computer system.

In some embodiments, the computer system becomes dust-fouled when sufficient dust has built up on at least one computer system component to interfere with a normal operation of the component.

In some embodiments, the system generates a dust-fouling model for the computer system by feeding dust at a controlled rate into the computer system while the computer system is operating. The system then samples performance parameters from the computer system until the computer system is dust-fouled. The system uses the sampled performance parameters to generate a mathematical dust-fouling model for predicting when the computer system is becoming dust-fouled.

In some embodiments, when determining if the computer system is becoming dust-fouled, the system samples performance parameters from the computer system during operation. The system then inputs the values of the performance parameters into the dust-fouling model and analyzes the output from the dust-fouling model to determine if the computer system is becoming dust-fouled.

In some embodiments, when sampling performance parameters, the system collects samples of the performance parameter from a telemetry harness.

In some embodiments, the performance parameter is a physical parameter, which includes at least one of: a temperature; a relative humidity; a cumulative or differential vibration; a fan speed; an acoustic signal; a current; a voltage; a time-domain reflectometry (TDR) reading; or another physical property that indicates an aspect of performance of the system.

In some embodiments, the performance parameter is a software metric, which includes at least one of: a system throughput; a transaction latency; a queue length; a load on a central processing unit; a load on a memory; a load on a cache; I/O traffic; a bus saturation metric; FIFO overflow statistics; or another software metric that indicates an aspect of performance of the system.

### BRIEF DESCRIPTION OF THE FIGURES

FIG. 1 illustrates computer system in accordance with embodiments of the present invention.

FIG. 2 presents a flowchart illustrating the process of generating a dust-fouling model in accordance with embodiments of the present invention.

FIG. 3 presents a flowchart illustrating the process of using a dust-fouling model to prevent dust-fouling in accordance with embodiments of the present invention.

### DETAILED DESCRIPTION

The following description is presented to enable any person skilled n the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the claims.

### Computer System

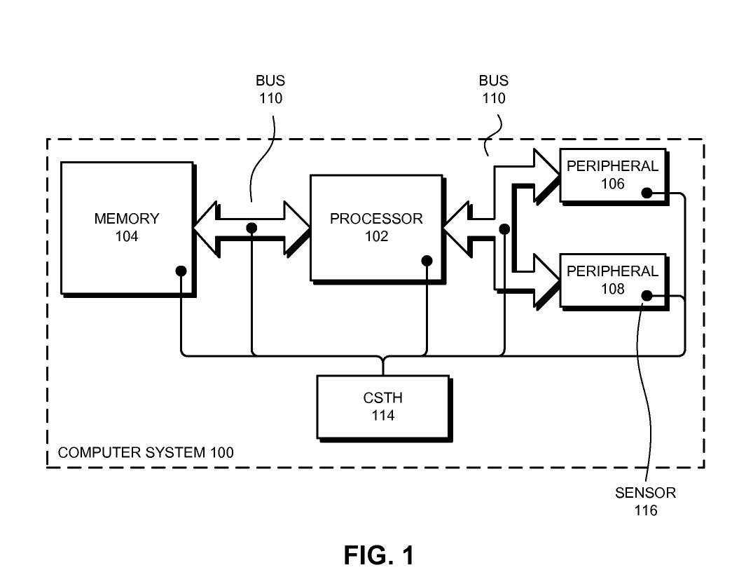

FIG. 1 illustrates computer system 100 in accordance with embodiments of the present invention. Computer system 100 includes processor 102, memory 104, peripheral 106, and peripheral 108. Processor 102 can be any type of processor that executes program code, such as a microprocessor. Memory 104 is coupled to processor 102 through bus 110 and contains data and program code for processor 102. Bus 110 serves as a communication channel for data and program code between processor 102 and memory 104. Peripherals 106 and 108 can be any type of peripheral components, such as video cards, interface cards, or network cards. Bus 112 serves as a communication channel for data and commands between processor 102 and peripherals 106 and 108.

Although we use computer system 100 for purposes of illustration, embodiments of the present invention can be applied to other systems, such as desktop computers, workstations, embedded computer systems, laptop computer systems, servers, blades, networking components, peripheral cards, automated manufacturing systems, and other types of computer systems. Furthermore, embodiments of the present invention can be applied to individual components, separate field-replaceable units (FRUs), or entire systems.

In some embodiments of the present invention, computer system 100 includes Continuous System Telemetry Harness (CSTH) 114. CSTH 114 is described in more detail in U.S. Pat. No. 7,020,802, entitled “Method and Apparatus for Monitoring and Recording Computer System Performance Parameters,” by inventors Kenny C. Gross and Larry G. Votta, which is hereby incorporated by reference to explain the functioning of a CSTH.

In these embodiments, CSTH 114 is coupled to a number of sensors 116 on components in computer system 100. CSTH 114 uses sensors 116 to sample system performance parameters, which can then be used to determine the performance of the associated components. For example, CSTH 114 can sample physical system performance parameters such as: temperatures, relative humidity, cumulative or differential vibrations, fan speed, acoustic signals, currents, voltages, time-domain reflectometry (TDR) readings, and miscellaneous environmental variables. On the other hand, CSTH 114 can sample software system performance parameters such as: system throughput, transaction latencies, queue lengths, load on the central processing unit, load on the memory, load on the cache, I/O traffic, bus saturation parameters, FIFO overflow statistics, and various other system performance parameters gathered from software. Furthermore, CSTH can sample so-called “canary parameters” associated with distributed synthetic user transactions periodically generated for performance measuring purposes, such as user wait times and other Quality-Of-Service (QOS) parameters measured during execution of distributed synthetic-user transactions.

Air Cooling

In embodiments of the present invention, computer system 100 is air-cooled (i.e., air currents are used to remove excess heat from computer system 100). Generally, in air-cooled systems, external air is drawn into a computer system and flows through the computer system in one direction. For example, the air can flow from bottom to top, from front to back, or (less commonly) from side to side. The air-flow can be created by one or more fans that are oriented to force air through the computer system in the given direction.

In embodiments of the present invention, the computer system includes a number of reversible fans. These fans ordinarily move air through the computer system in one direction (e.g., from front to back), however, the fans can be configured to move air through the computer system in the opposite direction (e.g., from back to front). When the fans move air through the computer system in the opposite direction, dust can be dislodged from dust-fouled components and blown out of the computer system.

### Generating a Dust-Fouling Model

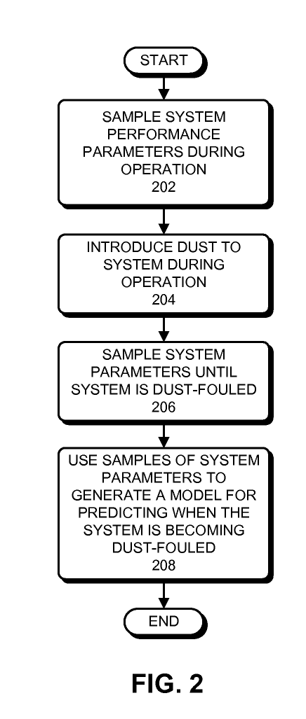

FIG. 2 presents a flowchart illustrating the process of generating a dust-fouling model in accordance with embodiments of the present invention. During the process, in a testing laboratory the system samples system performance parameters as dust builds up within computer system 100 and then uses the samples of the system performance parameters to generate a dust-fouling model. The dust-fouling model can then be used to predict when computer system 100 (or similar computer systems) may become dust-fouled.

In some embodiments of the present invention, the dust-fouling model is generated using a statistical and/or pattern recognition technique such as a non-linear, non-parametric (NLNP) regression (e.g., a Multivariate State Estimation Technique (MSET) technique), a multiple regression technique, a neural network technique, or another type of technique.

The process starts when the system samples a set of performance parameters for computer system 100 during operation (step 202). In this step, the system establishes the values of the system performance parameters before the system is dust-fouled.

Next, dust is introduced into computer system 100 (step 204). Note that introducing dust can involve feeding a predetermined amount of dust into the computer system 100's air intakes. When feeding dust to computer system 100, the dust is fed at a rate significantly higher than the rate at which dust is encountered under typical operating conditions. However, the dust is fed slowly enough to allow computer system 100 to manifest symptoms of dust-fouling (e.g., overheating).

The system then samples the system parameters until computer system 100 is dust-fouled (step 206). Next, from the samples of the system parameters, the system generates a model for predicting when the computer system is becoming dust-fouled (step 208).

### Using the Dust-Fouling Model to Prevent Dust-Fouling

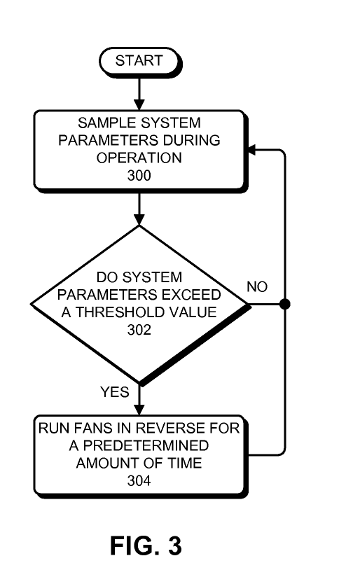

FIG. 3 presents a flowchart illustrating the process of using a dust-fouling model to prevent dust-fouling in accordance with embodiments of the present invention. The process starts when computer system 100 samples system performance parameters during operation (step 300).

The system then inputs the values of the samples into the dust-fouling model to determine if system parameters exceed a threshold value (step 302). In other words, the system uses the dust-fouling model to detect the onset of dust-fouling on internal components (and the degree of dust-fouling). If the system parameters have not exceeded the threshold value, the system returns to step 300 to collect the next sample of the system parameters. Note that the system may wait for a predetermined time before re-sampling the system parameters (e.g. 1 minute, 1 hour, 1 day, etc.).

Otherwise, the system runs the fans in reverse for a predetermined amount of time (step 304). Running the fans in reverse temporarily reverses the air flow in all fans in the server (primary cooling fans as well as power supply fans). This flow reversal dislodges and disperses dust from within computer system 100.

Using the dust-fouling model to perform pattern recognition provides the system with continuous signal validation, sensor operability validation, and allows the system to distinguish between altered correlation patterns among multiple variables that arise from dust-fouling and the conditions that might cause a temperature threshold to be crossed in the absence of dust-fouling (e.g., failure of air conditioning in a datacenter or the intake of hot air from an improperly positioned neighboring computer system).

Note that instead of using pattern recognition to trigger the flow reversal, the flow-reversal could optionally occur periodically (e.g., once per 7 days, etc). However, there is an efficiency cost associated with flow reversal. To set up all computer systems with periodic flow reversal at fixed intervals creates a situation where computer systems that are exposed to more airborne dust may not be reversing their airflow frequently enough to assure low temperature operation, while computer systems in environments with less airborne dust are penalized with too-frequent reversals.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A method for preventing dust-fouling in a computer system, comprising:
operating the computer system with fans circulating air through the computer system in one direction;
determining if the computer system is becoming dust-fouled; and
if so, reversing the fans to circulate air through the computer system in the opposite direction to dislodge and disperse dust from the computer system.

2. The method of claim 1, wherein the computer system is dust-fouled when sufficient dust has built up on at least one computer system component to interfere with a normal operation of the component.

3. The method of claim 1, wherein the method further comprises generating a dust-fouling model for the computer system by:
feeding dust at a controlled rate into the computer system while the computer system is operating;
sampling performance parameters from the computer system until the computer system is dust-fouled; and
using the sampled performance parameters to generate a mathematical dust-fouling model for predicting when the computer system is becoming dust-fouled.

4. The method of claim 3, wherein determining if the computer system is becoming dust-fouled involves:
sampling performance parameters from the computer system during operation;
inputting the values of the performance parameters into the dust-fouling model; and
analyzing the output from the dust-fouling model to determine if the computer system is becoming dust-fouled.

5. The method of claim 4, wherein sampling performance parameters involves collecting samples of the performance parameter using a telemetry harness that is coupled to at least one sensor in the computer system.

6. The method of claim 1, wherein the performance parameter is a physical parameter, which includes at least one of: a temperature; a relative humidity; a cumulative or differential vibration; a fan speed; an acoustic signal; a current; a voltage; a time-domain reflectometry (TDR) reading; or another physical property that indicates an aspect of performance of the system.

7. The method of claim 1, wherein the performance parameter is a software metric, which includes at least one of: a system throughput; a transaction atency; a queue length; a load on a central processing unit; a load on a memory; a load on a cache; I/O traffic; a bus saturation metric; FIFO overflow statistics; or another software metric that indicates an aspect of performance of the system.

8. An apparatus that prevents dust-fouling in a computer system, comprising:
one or more fans configured to circulate air through the computer system in one direction during operation;
a monitoring mechanism coupled to the fans, wherein the monitoring mechanism is configured to determine if the computer system is becoming dust-fouled; and
wherein if the computer system is becoming dust-fouled, the monitoring mechanism is configured to reverse the fans to circulate air through the computer system in the opposite direction to dislodge and disperse dust from the computer system.

9. The apparatus of claim 8, wherein the computer system is dust-fouled when sufficient dust has built up on at least one computer system component to interfere with a normal operation of the component.

10. The apparatus of claim 8, further comprising a model-generation mechanism configured to:
feed dust at a controlled rate into the computer system while the computer system is operating;
sample performance parameters from the computer system until the computer system is dust-fouled; and
use the sampled performance parameters to generate a mathematical dust-fouling model for predicting when the computer system is becoming dust-fouled.

11. The apparatus of claim 10, wherein while determining if the computer system is becoming dust-fouled, the monitoring mechanism is configured to:
sample performance parameters from the computer system during operation;
input the values of the performance parameters into the dust-fouling model; and
analyze the output from the dust-fouling model to determine if the computer system is becoming dust-fouled.

12. The apparatus of claim 11, further comprising a telemetry harness coupled to at least one sensor in the computer system, wherein sampling performance parameters involves using the telemetry harness to collect samples of the performance parameter from the sensor.

13. The apparatus of claim 8, wherein the performance parameter is a physical parameter, which includes at least one of: a temperature; a relative humidity; a cumulative or differential vibration; a fan speed; an acoustic signal; a current; a voltage; a time-domain reflectometry (TDR) reading; or another physical property that indicates an aspect of performance of the system.

14. The apparatus of claim 8, wherein the performance parameter is a software metric, which includes at least one of: a system throughput; a transaction latency; a queue length; a load on a central processing unit; a load on a memory; a load on a cache; I/O traffic; a bus saturation metric; FIFO overflow statistics; or another software metric that indicates an aspect of performance of the system.

15. A computer system for preventing dust-fouling in a computer system, comprising:
a processor;
a memory;
one or more fans configured to circulate air through the computer system in one direction during operation;
a monitoring mechanism coupled to the fans, wherein the monitoring mechanism is configured to determine if the computer system is becoming dust-fouled; and
wherein if the computer system is becoming dust-fouled, the monitoring mechanism is configured to reverse the fans to circulate air through the computer system in the opposite direction to dislodge and disperse dust from the computer system.

16. The computer system of claim 15, wherein the computer system is dust-fouled when sufficient dust has built up on at least one computer system component to interfere with a normal operation of the component.

17. The computer system of claim 15, further comprising a model-generation mechanism configured to:
feed dust at a controlled rate into the computer system while the computer system is operating;
sample performance parameters from the computer system until the computer system is dust-fouled; and
use the sampled performance parameters to generate a mathematical dust-fouling model for predicting when the computer system is becoming dust-fouled.

18. The computer system of claim 17, wherein while determining if the computer system is becoming dust-fouled, the monitoring mechanism is configured to:
sample performance parameters from the computer system during operation;
input the values of the performance parameters into the dust-fouling model; and
analyze the output from the dust-fouling model to determine if the computer system is becoming dust-fouled.

19. The computer system of claim 18, further comprising a telemetry harness coupled to at least one sensor in the computer system, wherein sampling performance parameters involves using the telemetry harness to collect samples of the performance parameter from the sensor.

20. The computer system of claim 15, wherein the performance parameter is a physical parameter, which includes at least one of: a temperature; a relative humidity; a cumulative or differential vibration; a fan speed; an acoustic signal; a current; a voltage; a time-domain reflectometry (TDR) reading; or another physical property that indicates an aspect of performance of the system.

21. The computer system of claim 15, wherein the performance parameter is a software metric, which includes at least one of: a system throughput; a transaction latency; a queue length; a load on a central processing unit; a load on a memory; a load on a cache; I/O traffic; a bus saturation metric; FIFO overflow statistics; or another software metric that indicates an aspect of performance of the system.

22. A model-generation mechanism, comprising:
a dust feeding mechanism configured to feed dust at a controlled rate into the computer system while the computer system is operating;
a sampling mechanism configured to sample performance parameters from the computer system until the computer system is dust-fouled; and
wherein the model generation mechanism is configured to use the sampled performance parameters to generate a mathematical dust-fouling model for predicting when the computer system is becoming dust-fouled.

23. The model-generation mechanism of claim 22, further comprising a telemetry harness coupled to at least one sensor in the computer system, wherein sampling performance parameters involves using the telemetry harness to collect samples of the performance parameter from the sensor.

24. The model-generation mechanism of claim 22, wherein the performance parameter is a physical parameter, which includes at least one of: a temperature; a relative humidity; a cumulative or differential vibration; a fan speed; an acoustic signal; a current; a voltage; a time-domain reflectometry (TDR) reading; or another physical property that indicates an aspect of performance of the system.

25. The model-generation mechanism of claim 22, wherein the performance parameter is a software metric, which includes at least one of: a system throughput; a transaction latency; a queue length; a load on a central processing unit; a load on a memory; a load on a cache; I/O traffic; a bus saturation metric; FIFO overflow statistics; or another software metric that indicates an aspect of performance of the system.

26. The model-generation mechanism of claim 22, wherein the model-generation mechanism is configured to generate the mathematical model using a non-linear, non-parametric (NLNP) regression, a Multivariate State Estimation Technique (MSET) technique, a multiple regression technique, a neural network technique, or another statistical and/or pattern recognition technique.
